(19) United States
(12) Patent Application Publication
(10) Pub. No.: US 2014/0050031 A1
(43) Pub. Date: Feb. 20, 2014

(54) SEMICONDUCTOR MEMORY DEVICE CAPABLE OF REDUCING READ TIME

(71) Applicant: Go SHIKATA, Yokohama-shi (JP)

(72) Inventor: Go SHIKATA, Yokohama-shi (JP)

(21) Appl. No.: 13/721,249

(22) Filed: Dec. 20, 2012

Related U.S. Application Data
(60) Provisional application No. 61/683,544, filed on Aug. 15, 2012.

(51) Int. Cl. H01L 29/78; G11C 16/14

(52) U.S. Cl. CPC H01L 29/78; G11C 16/14
USPC 365/185.25; 257/314

(57) ABSTRACT

According to one embodiment, a semiconductor memory device includes a semiconductor substrate of a first conductivity type, a first well region of a second conductivity type, a second well region of the first conductivity type, a memory string, a bit line, a source line and a first transistor. The bit line is connected to one end of the memory string and the source line is connected to the other end of the memory string. The first transistor is arranged on the second well region, has first and second terminals and includes a gate insulating film with first film thickness. The first terminal of the first transistor is connected to the source line and the second terminal thereof is connected to the second well region.

### CROSS-REFERENCE TO RELATED APPLICATIONS

This application claims the benefit of U.S. Provisional Application No. 61/683,544, filed Aug. 15, 2012, the entire contents of which are incorporated herein by reference.

### FIELD

Embodiments described herein relate generally to a nonvolatile semiconductor memory device such as a NAND flash memory, for example.

### BACKGROUND

A NAND flash memory of multi levels in which plural-bit data is stored in one memory cell is developed. Among the multi-level NAND flash memories, a NAND flash memory in which a part of multi-level data is set by use of a negative threshold voltage is provided.

In the case of a NAND flash memory using a negative threshold voltage, the read speed may be lowered in some cases at the data read time. Further, if a negative threshold voltage is used, there occurs a problem that it is necessary to use high-voltage transistors with a large size and the chip size becomes large.

### BRIEF DESCRIPTION OF THE DRAWINGS

FIG. 1 is a configuration diagram showing a semiconductor memory device according to a first embodiment.

FIG. 2 is a diagram for illustrating the operation of the first embodiment.

FIG. 3A is a plan view showing the structure of transistors according to the first embodiment and FIG. 3B is a plan view showing a comparison example.

FIG. 4 is a perspective view concretely showing FIG. 3A.

FIG. 5 is a configuration diagram showing a semiconductor memory device according to a second embodiment.

FIG. 6 is a configuration diagram showing a semiconductor memory device according to a third embodiment.

FIG. 7 is a perspective view concretely showing the configuration of the semiconductor memory device according to the third embodiment.

FIG. 8 is a configuration diagram showing a semiconductor memory device according to a fourth embodiment.

FIG. 9 is a configuration diagram showing a semiconductor memory device according to a fifth embodiment.

### DETAILED DESCRIPTION

In general, according to one embodiment, a semiconductor memory device includes a semiconductor substrate of a first conductivity type, a first well region of a second conductivity type, a second well region of the first conductivity type, a memory string, a bit line, a source line and a first transistor. The first well region of the second conductivity type is arranged in the semiconductor substrate of the first conductivity type. The second well region of the first conductivity type is arranged in the first well region. The memory string is arranged in the second well region and includes a plurality of memory cells and first and second select transistors. The bit line is connected to one end of the memory string and the source line is connected to the other end of the memory string. The first transistor is arranged on the second well region, has first and second terminals and includes a gate insulating film with first film thickness. The first terminal of the first transistor is connected to the source line and the second terminal thereof is connected to the second well region.

For example, in the case of a NAND flash memory using a negative threshold voltage, the voltage of a selected word line is set to approximately 0 V, the voltage of a non-selected word line is set to approximately 6 V and the source of the memory cell and the well region having the memory cell formed therein are biased to a positive voltage at the data read time to read and verify a negative threshold voltage. Further, in the case of reading a memory cell in which a positive threshold voltage is set (Positive Level Sense), the potential of the source line is made to bounce according to a data pattern. In order to prevent this, the source of the memory cell and a well region having the memory cell formed therein are biased to a positive voltage (for example, 1 V) to read a positive threshold voltage. At this time, the well region is shorted to the source line via a shorting circuit. If the shorting circuit is configured by use of an N-channel transistor and arranged in the semiconductor substrate between a memory cell array and a sense amplifier, for example, it is necessary to configure the N-channel transistor by use of a high-voltage transistor since the source line and the well region of the N-channel transistor are set to erase voltage VERA (for example, 20 V) at the erase operation time. However, the channel length and the size of the diffusion layer of the high-voltage transistor are large, and therefore, a problem that the chip size becomes large occurs. Therefore, it is desired to rapidly read data and prevent an increase in the chip size.

Next, the embodiments are explained with reference to the drawings. In the embodiments, the same symbols are attached to the same portions.

(First Embodiment)

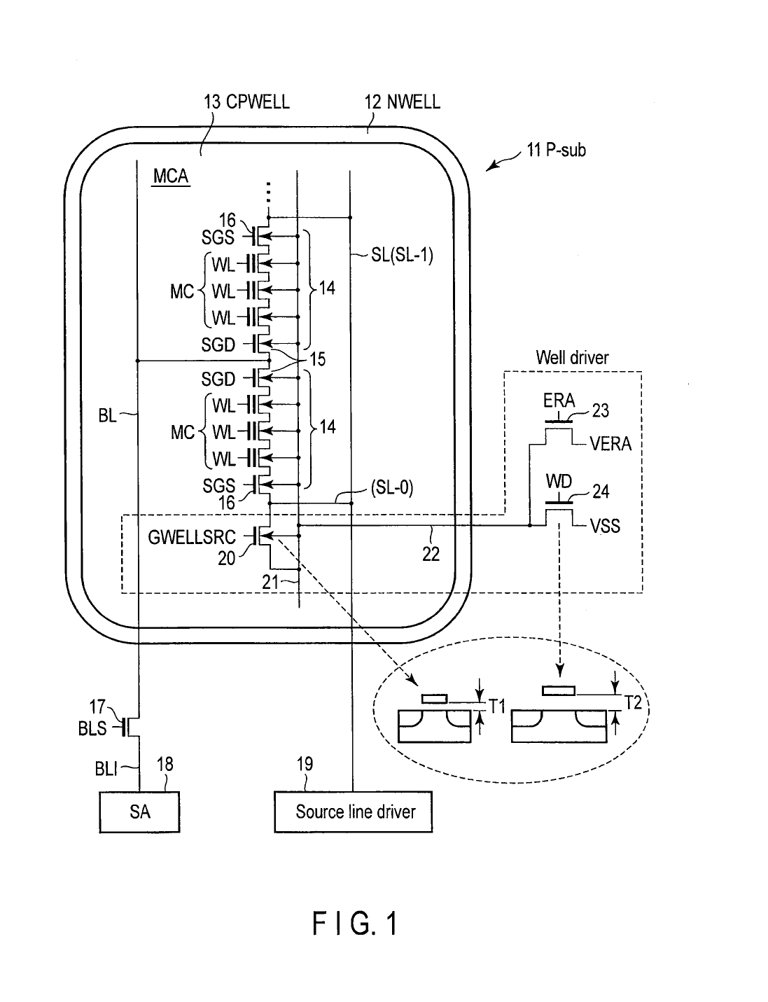

FIG. 1 shows the configuration of a portion of a semiconductor memory device, for example, a NAND flash memory according to a first embodiment. For convenience of the explanation, only the configuration associated with one bit line is shown in each embodiment.

In FIG. 1, an N-type well region (that is hereinafter referred to as a first well region) 12 (NWELL) is formed in a P-type semiconductor substrate 11 (P-sub). A P-type well region (that is hereinafter referred to as a second well region) 13 (CPWELL) is formed in the first well region 12. Memory cell array MCA is formed in the second well region 13.

Memory cell array MCA is configured by a plurality of NAND strings (that are referred to as memory strings) 14. In FIG. 1, as the memory strings 14, only two memory strings 14 arranged in the direction of bit line BL are shown, but in practice, a plurality of memory strings having the above configuration are also arranged in a direction perpendicular to bit line BL.

Each memory string 14 includes a plurality of series-connected memory cells MC, a first select transistor 15 connected to the drain side of memory cells MC and a second select transistor 16 connected to the source side thereof. The control gates of the respective memory cells are connected to corresponding word lines WL, the gate electrode of the first select transistor 15 is connected to first select signal line SGD and the gate electrode of the second select transistor 16 is connected to second select signal line SGS.

Each memory string 14 is connected to bit line BL via the first select transistor 15 and is connected to source line SL via the second select transistor 16.

Bit line BL is connected to bit line BLI via a transistor 17 and a sense amplifier 18 is connected to bit line BLI. Further, source line SL is connected to a source line driver 19. The transistor 17, sense amplifier 18 and source line driver 19 are formed in the semiconductor substrate 11 and the transistor 17 is configured by a high-voltage transistor as will be described later.

Further, as will be described later, one end of the second select transistor 16 in each memory string 14 that is arranged in a position nearest to the sense amplifier 18, for example, is connected to a low-voltage N-channel transistor 20.

Specifically, the first end portion (drain) of the transistor 20 is connected to the source (source line SL) of the second select transistor 16 and the second end portion (source) thereof is connected to the second well region 13. That is, the second end portion is connected to an interconnection 21 used for supplying a potential to the second well region 13. Signal GWLLSRC is supplied to the gate electrode of the transistor 20. The transistor 20 short-circuits source line SL to the second well region 13 based on signal GWLLSRC.

One-side ends of transistors 23, 24 that configure a well driver are connected to the interconnection 21 via an interconnection 22. The transistors 23, 24 are high-voltage transistors and arranged in the semiconductor substrate 11. The other end of the transistor 23 is applied with erase voltage VERA and the other end of the transistor 24 is applied with ground voltage VSS.

Signal ERA is supplied to the gate electrode of the transistor 23 and the transistor 23 applies erase voltage VERA to the P-type well region 13 based on signal ERA at the memory cell erase time. Signal WD is supplied to the gate electrode of the transistor 24 and the transistor 24 applies ground voltage VSS to the P-type well region 13 based on signal WD at the memory cell drive time. In this case, the transistor 24 sets CPWELL at Vss not only at the time when it drives the memory cell but also in a normal mode.

As described above, the transistor 20 is a low-voltage transistor and the transistors 17, 23, 24 are high-voltage transistors. Therefore, film thickness T1 of the gate insulating film of the transistor 20 is made thinner than film thickness T2 of the gate insulating film of the transistors 17, 23, 24. Further, the channel length of the transistor 20 and the sizes of the source and drain thereof are set smaller than those of the transistors 17, 23, 24.

As described above, the transistors 17, 23, 24 are configured by transistors with withstand voltages higher than that of the transistor 20. Therefore, the transistors are formed in the semiconductor substrate 11. As a result, the sense amplifier 18 is protected by means of the high-voltage transistor 17.

For example, data of three bits or more (eight levels or more) are stored in each memory cell MC. A portion of the threshold voltage of data with eight levels or more is set by use of a negative threshold voltage.

In a NAND flash memory having a negative threshold voltage set therein, the voltage of a selected word line is set to approximately 0 V, the voltage of a non-selected word line is set to approximately 6 V and the source of the memory cell and the well region 13 having the memory cell formed therein are biased to a positive voltage at the data read time to read and verify a negative threshold voltage. At this time, the second well region 13 is shorted to source line SL by means of the transistor 20 acting as a shorting circuit and is charged by means of the source line driver 19 via source line SL.

Further, also, at the time of reading a memory cell in which a positive threshold voltage is set, the potential of source line SL and the second well region 13 having the memory cell formed therein are biased to a positive voltage (for example, 1 V) to read a positive threshold voltage in order to prevent the potential of source line SL from being made to bounce according to a data pattern. At this time, the second well region 13 is shorted to source line SL by means of the transistor 20 acting as a shorting circuit and is charged by means of the source line driver 19 via source line SL.

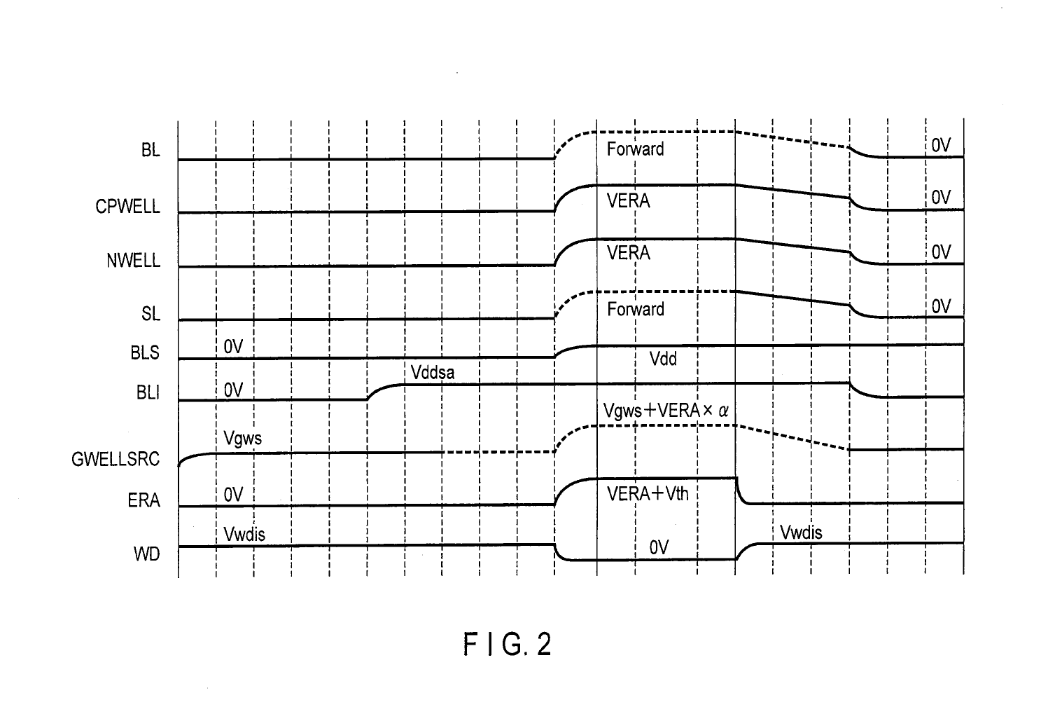

FIG. 2 shows the operation at the erase time. As shown in FIG. 2, first, signal GWELLSRC is set to Vgws (4 V), for example, to turn on the transistor 20.

Next, bit line BLI on the side of the sense amplifier 18 is charged to Vddsa (2.5 V), for example, by means of the sense amplifier 18.

After this, signal ERA is set to VERA+Vth (Vth indicates the threshold voltage of an N-channel transistor) to turn on the transistor 23. Therefore, the second well region 13 is charged to erase voltage VERA (for example, 20 V) via the transistor 23. As a result, bit line BL and source line SL are forward-biased and charged to a forward voltage (Forward).

Further, at this time, signal GWELLSRC supplied to the gate electrode of the transistor 20 is raised to Vgws+VERA×α by capacitive coupling with the second well region 13 or source line SL. In this case, α indicates the coupling ratio between the second well region 13 or source line SL and GWELLSRC. Thus, gate-source voltage Vgs, drain-source voltage Vds and substrate-source voltage Vbs of the transistor 20 are not simultaneously set to a high voltage. Therefore, no stress is applied to the transistor 20 at the erase time. As a result, source line SL and the second well region 13 can be shorted by means of the low-voltage transistor 20.

On the other hand, if the erase operation is completed, supply of erase voltage VERA is interrupted. Then, charges of the second well region 13, first well region 12 and source line SL are discharged. Bit line BL is discharged by capacitive coupling with the second well region or source line SL. However, since bit line BL is discharged via the capacitive coupling, there occurs a possibility that charges will not completely be discharged. Therefore, bit line BL is equalized with a node in the memory cell array such as the second well region 13 or source line SL, and is discharged.

According to the first embodiment, the transistor 20 is arranged between one end of the memory string 14 on the source side and the second well region 13 and the second well region 13 and source line SL are shorted by turning on the transistor 20 at the erase time. Therefore, if erase voltage VERA is applied to the second well region 13 at the erase time, the first well region 12, source line SL and bit line BL are set to erase voltage VERA. However, since the transistor 20 is arranged on the second well region 13, high voltages are not applied as gate-source voltage Vgs, drain-source voltage Vds and substrate-source voltage Vbs of the transistor 20. Therefore, the transistor 20 can be formed of a low-voltage transistor. Thus, the chip size can be reduced.

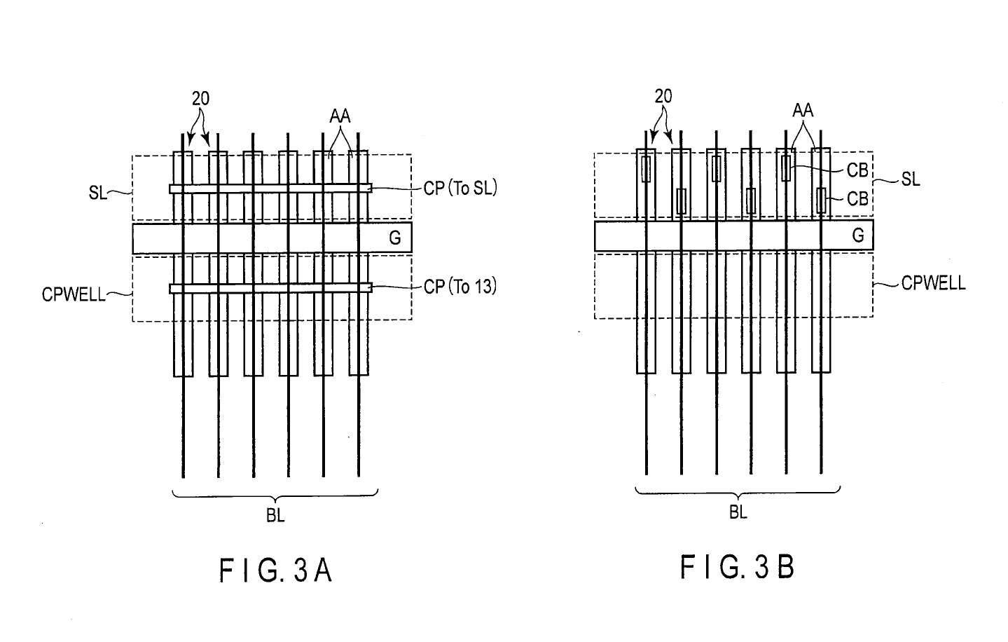

FIG. 3A shows a plurality of transistors 20 arranged in memory cell array MCA. As shown in FIG. 3A, the transistors 20 include active regions AA acting as source and drain regions and gate electrode G is commonly arranged for the transistors 20. The gate width of the transistor 20 is set with the same pitch as that of the memory cells.

The gate length of the transistor 20 is set to the same as those of the first and second select transistors 15, 16 or to the width larger than the latter.

In the case of the first embodiment, the transistor 20 is used to short source line SL to the second well region 13. Therefore, the source regions and drain regions of the transistors 20 shown in FIG. 3A are commonly connected by means of linear contacts CP and can be formed to function as one transistor. Therefore, even when elements are further miniaturized, contacts CP can be easily formed.

Contacts CB can be formed as shown in the comparison example shown in FIG. 3B. If the transistor 20 is used as a select transistor of bit line BL, formation of contact CB becomes difficult as miniaturization of the elements is further advanced, but attention must be paid not to short the same to adjacent bit line BL. However, in the case of the first embodiment, since the source regions and drain regions of the transistors 20 shown in FIG. 3B are commonly connected, no problem occurs even if adjacent contacts CB are shorted.

According to the first embodiment, the total channel width can be made large by permitting the plural transistors 20 to function as one transistor. Therefore, in the read and the verify, when the second well region 13 is charged via source line SL, the potential of the second well region 13 can be made to rapidly follow the potential of source line SL. As a result, the read and the verify can be rapidly performed.

Charging of source line SL is terminated when the level of source line SL has reached a set value. Therefore, if charging of the second well region 13 is slower than charging of source line SL, charging of source line SL will be terminated before the second well region 13 is sufficiently charged. In this case, charge sharing occurs later between source line SL and the second well region 13 and the level of source line SL is lowered. Therefore, in order to maintain the level of source line SL after charging of source line SL is terminated, it is necessary to supply a constant current (for example, 200 μA) to the source line. As a result, it is necessary to take a long time until the level of source line SL is stabilized and the read and verify time becomes long.

However, according to the first embodiment, the potential of the second well region 13 can be caused to rapidly follow the potential of source line SL by permitting the plural transistors 20 to function as one transistor having the large total channel width. Therefore, the read of data and the verify read operation at the time of the program can be rapidly performed.

Further, since it is not necessary to use a high-voltage transistor with the large size, the chip size can be prevented from being increased.

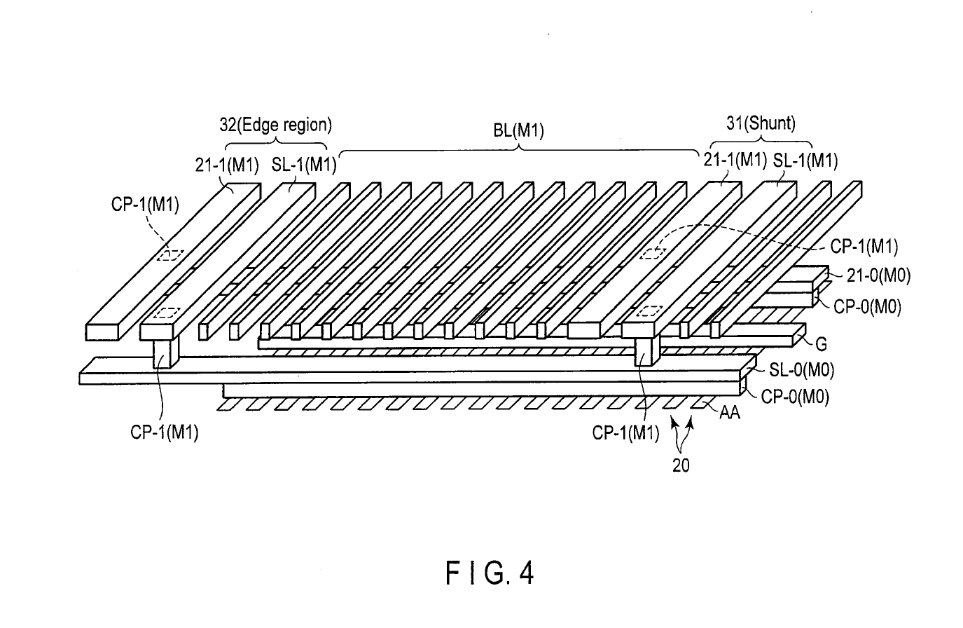

FIG. 4 is a perspective view concretely showing FIG. 3A.

Active regions AA acting as the source and drain regions of a plurality of transistors 20 are commonly connected via linear contacts CP-0. Source line SL-0 and an interconnection 21-0 connected to the second well region 13 are formed on contacts CP-0. Contacts CP-0, source line SL-0 and interconnection 21-0 are formed by use of first-layered metal interconnection M0. In FIG. 4, indices “-0” are attached to the interconnection and contact formed by use of first-layered metal interconnection M0.

A plurality of bit lines BL, source lines SL-1 and interconnections 21-1 formed by use of second-layered metal interconnection M1 are arranged in a direction perpendicular to source line SL-0 and interconnection 21-0 above source line SL-0 and interconnection 21-0. In FIG. 4, indices “-1” are attached to the interconnection and contact formed by use of second-layered metal interconnection M1.

Source lines SL-1 and interconnections 21-1 are arranged in regions in which bit lines BL are not arranged in a shunt region 31 and/or edge region 32 of the memory cell array. In the shunt region 31 and/or edge region 32, source line SL-0 and interconnection 21-0 of first-layered metal interconnection M0 are electrically connected to source lines SL-1 and interconnections 21-1 of second-layered metal interconnection M1 via contacts CP-1, respectively.

With the above configuration, the interconnection 21 that supplies a potential to source line SL and the second well region 13 can be formed in memory cell array MCA having a plurality of bit lines BL arranged therein.

(Second Embodiment)

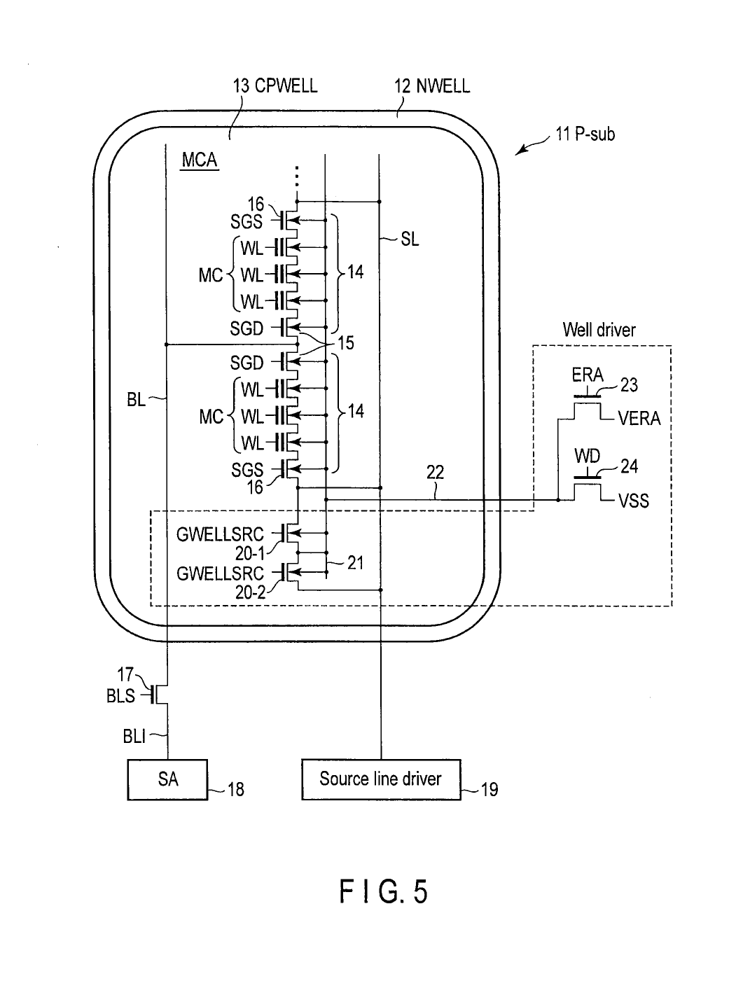

FIG. 5 shows a semiconductor memory device according to a second embodiment. In FIG. 5, the same symbols are attached to the same portions as those of the first embodiment and only the different portions are explained.

In the first embodiment, the shorting circuit that shorts source line SL to the second well region 13 is configured by use of one transistor 20.

However, in the second embodiment, the shorting circuit is configured by use of a plurality of transistors, for example, two transistors. That is, as shown in FIG. 5, transistors 20-1 and 20-2 are serially connected between one end of a memory string 14 on the source side and a second well region 13. The transistors 20-1, 20-2 are low-voltage transistors. Signal GWELLSRC is supplied to the gate electrodes of the transistors 20-1, 20-2 and the transistors 20-1, 20-2 are simultaneously turned on by use of signal GWELLSRC. That is, the transistors 20-1, 20-2 are simultaneously turned on by use of signal GWELLSRC at the data erase time and read time to short source line SL to the second well region 13.

According to the second embodiment, the shorting circuit is configured by use of the two series-connected transistors 20-1 and 20-2. Therefore, source line SL can be securely shorted to the second well region 13 in comparison with a case wherein the shorting circuit is configured by use of one transistor.

Further, since the transistors 20-1, 20-2 are configured by use of low-voltage transistors, source line SL can be shorted to the second well region 13 with a less increase in the area in comparison with a case wherein the transistor is configured by use of a high-voltage transistor.

(Third Embodiment)

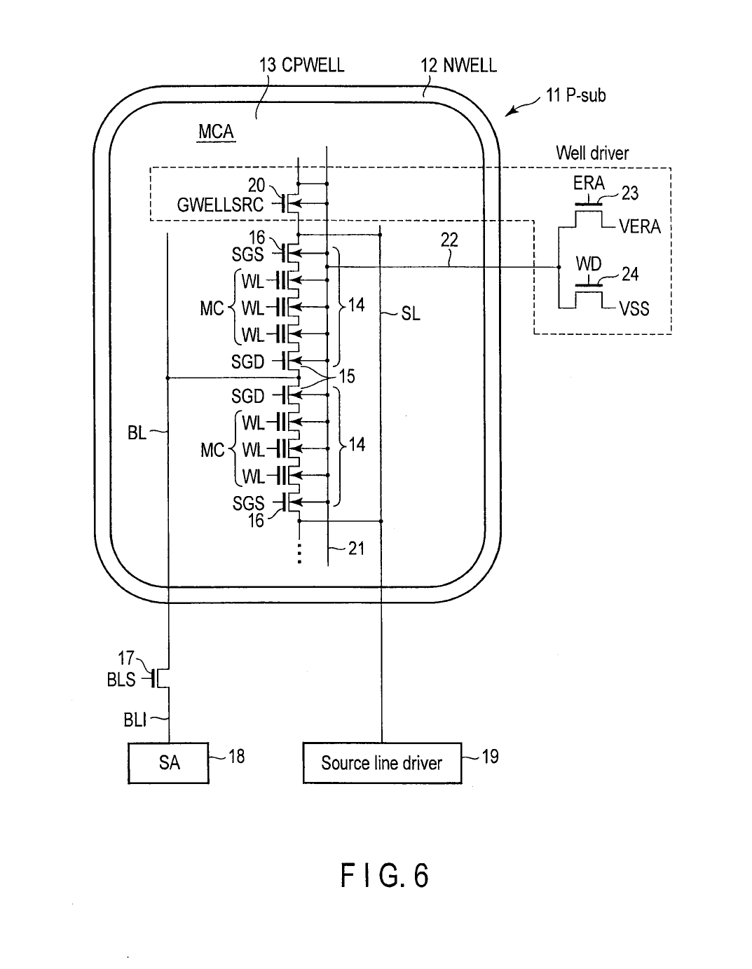

FIG. 6 shows a semiconductor memory device according to a third embodiment.

In the first and second embodiments, the transistors 20, 20-1, 20-2 for shorting are arranged on the side of the sense amplifier 18 in memory cell array MCA.

On the other hand, in the third embodiment, as shown in FIG. 6, a transistor 20 is arranged on the opposite side of the sense amplifier 18 in memory cell array MCA. That is, the transistor 20 is arranged between one end of a memory string 14 on the source side that is farthest apart from the sense amplifier 18 along bit line BL and a second well region 13 in memory cell array MCA. In other words, the transistor 20 is arranged between one end of the memory string 14 on the source side that is farthest apart from a source line driver 19 along source line SL and the second well region 13.

Transistors 23, 24 that configure a well driver are also formed in a semiconductor substrate 11 in a position separated from the source line driver 19 along source line SL. The transistors 23, 24 are connected to a portion of an interconnection 21 that is separated from the source line driver 19. The positions of the source line driver 19 and well driver are not limited to the above positions.

Also, in this case, like the second embodiment, the shorting circuit may be formed by use of a plurality of series-connected transistors.

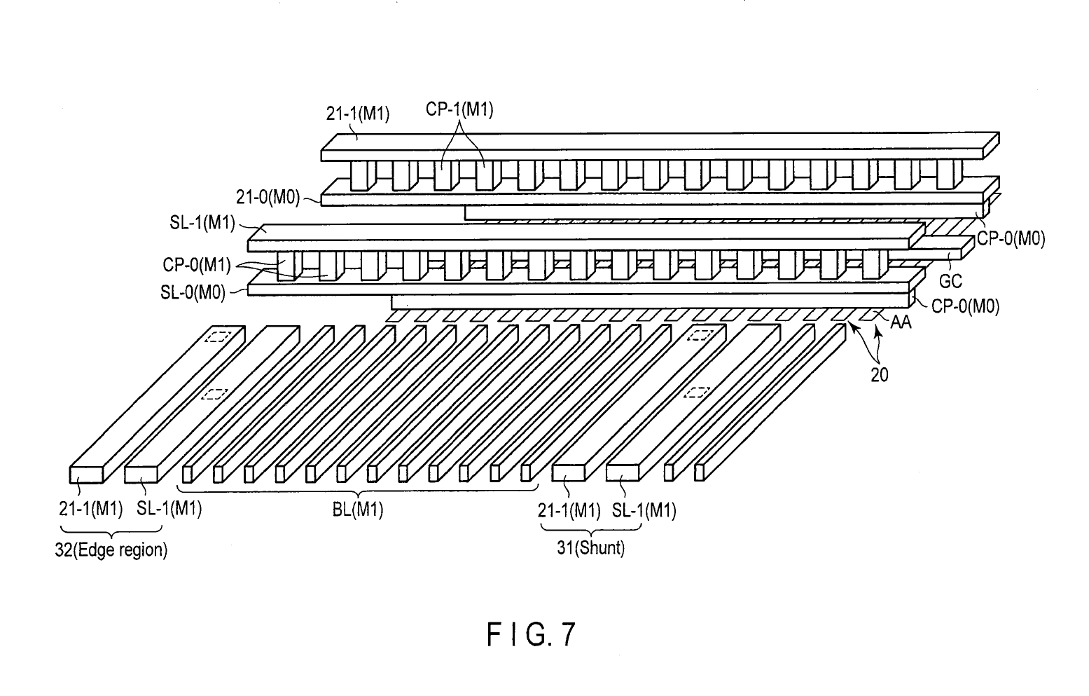

FIG. 7 concretely shows the relationship between the transistor 20 and bit line BL. In FIG. 7, a cell array arranged below bit line BL is omitted.

In the first embodiment, the transistor 20 is arranged on the sense amplifier 18 side of memory cell array MCA. Therefore, as shown in FIG. 4, interconnection SL-0 formed by use of first-layered metal interconnection layer M0 is arranged above the transistor 20 and plural bit lines BL formed by use of second-layered metal interconnection layer M1 are arranged above interconnection SL-0. As a result, as described before, contacts CP-1 that connect the interconnection 21-0 and source line SL-0 formed by use of first-layered metal interconnection layer M0 with the interconnection 21-1 and source line SL-1 formed by use of second-layered metal interconnection layer M1 can be arranged only in the shunt region 31 and the edge region 32 of memory cell array MCA.

On the other hand, in the third embodiment, as shown in FIG. 7, the transistor 20 is arranged in a region separated from the sense amplifier 18 in memory cell array MCA. In the above region, plural bit lines BL formed by use of second-layered metal interconnection layer M1 are not arranged above interconnection SL-0 formed by use of first-layered metal interconnection layer M0. Therefore, contacts CP-1 that connect the interconnection 21-0 and source line SL-0 formed by use of first-layered metal interconnection layer M0 with the interconnection 21-1 and source line SL-1 formed by use of second-layered metal interconnection layer M1 can be arranged in desired portions in a longitudinal direction of the interconnection 21-0 and source line SL-0. As a result, according to the third embodiment, the arrangement of contacts CP-1 that connect the interconnection 21-0 and source line SL-0 with the interconnection 21-1 and source line SL-1 is flexible.

Additionally, since the number of contacts can be increased, the interconnection resistance can be reduced and source line SL and the second well region 13 can be rapidly shorted.

Source lines SL-1 arranged in parallel with bit lines BL are connected to the source regions of the memory cells in the shunt region 31 and edge region 32 and the interconnections 21-1 are connected to the second well region in the shunt region 31 and edge region 32.

(Fourth Embodiment)

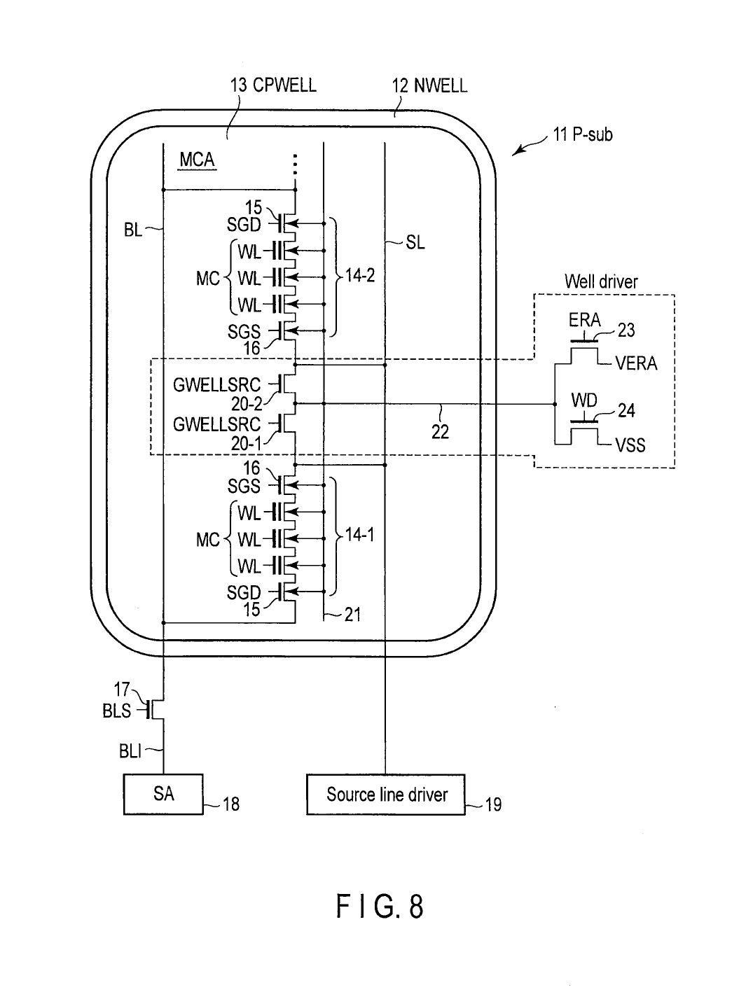

FIG. 8 shows a semiconductor memory device according to a fourth embodiment.

In the first embodiment, the transistor 20 for shorting is arranged near the sense amplifier 18 and, in the third embodiment, the transistor 20 for shorting is arranged in a portion separated from the sense amplifier 18.

On the other hand, in the fourth embodiment, transistors for shorting are arranged in the central portion of memory cell array MCA along source line SL (bit line BL).

That is, as shown in FIG. 8, transistors 20-1, 20-2 are arranged between two memory strings 14-1 and 14-2 that are arranged in the central portion of memory cell array MCA along source line SL.

The transistor 20-1 is connected to one end of the memory string 14-1 on the source side and the transistor 20-2 is connected to one end of the memory string 14-2 on the source side. The connection node of the transistors 20-1 and 20-2 is connected to transistors 23, 24 that configure a well driver. That is, the transistors 23, 24 that configure the well driver are formed in a portion of a semiconductor substrate 11 that lies in the central portion of memory cell array MCA in the direction of source line SL. The position of the well driver is not limited to the above position.

The transistors for shorting are arranged one for each of the memory strings 14-1 and 14-2, but plural transistors, for example, two transistors may be arranged for each of the memory strings 14-1 and 14-2.

As in the first embodiment, when source line SL and the second well region 13 are shorted by means of the transistor 20 arranged on the sense amplifier 18 side, the potential of the second well region 13 separated far apart from the transistor 20 requires a long time for charge transfer due to the presence of interconnection resistance and well resistance and the follow-up operation with respect to source line SL is degraded.

However, as in the fourth embodiment, when the transistors 20-1, 20-2 are arranged in the central portion of memory cell array MCA, the interconnection resistance and well resistance between the transistors 20-1, 20-2 and the portion of the second well region 13 becomes half in comparison with a case of the first embodiment. Therefore, the follow-up operation for charge transfer in the second well region 13 with respect to source line SL can be improved. As a result, the speed of the read and the verify can be increased.

(Fifth Embodiment)

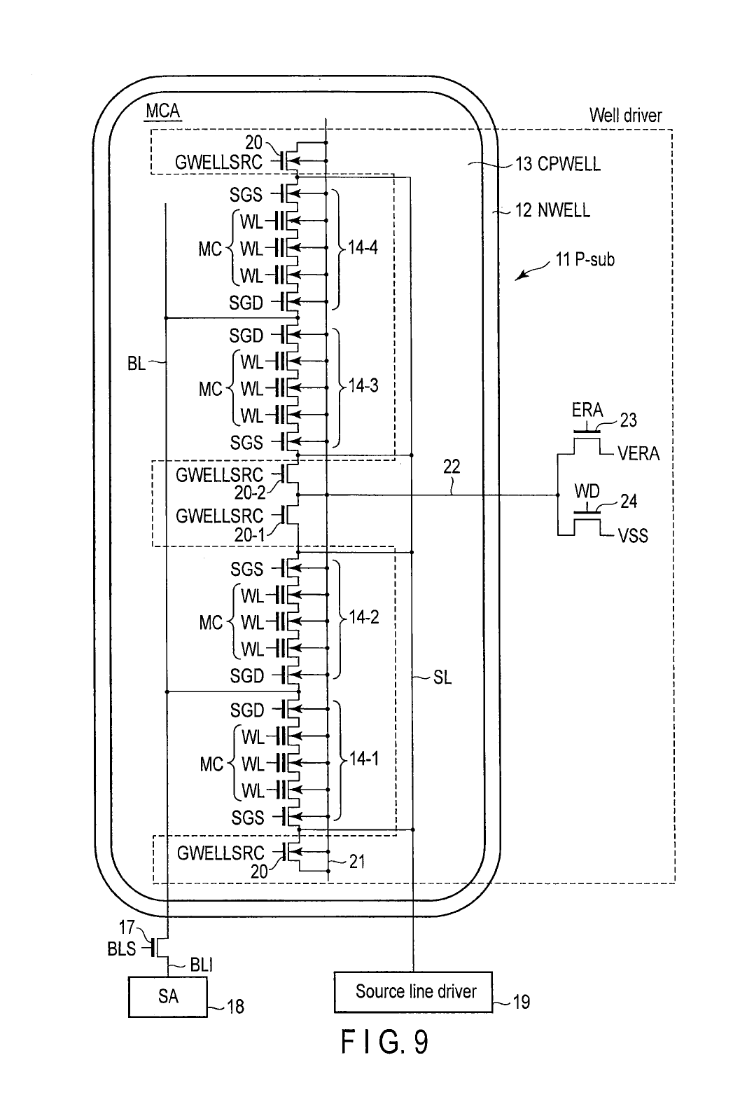

FIG. 9 shows a semiconductor memory device according to a fifth embodiment.

The fifth embodiment can be attained by unifying the first, third and fourth embodiments and plural transistors 20, 20-1, 20-2 that configure the shorting circuit are arranged in memory cell array MCA.

That is, one of a plurality of transistors 20 is connected to the source-side end portion of a memory string 14-1 that lies nearest to the side of a sense amplifier 18 among a plurality of memory strings 14-1 to 14-4 and another transistor 20 is connected to the source-side end portion of the memory string 14-4 that is arranged in a position farthest apart from the sense amplifier 18. Further, the transistors 20-1, 20-2 are respectively connected to the source-side end portions of the two memory strings 14-2, 14-3 that lie in the central portion.

In this case, the shorting circuit is not limited to one transistor 20, 20-1 or 20-2 and may be configured by a plurality of series-connected transistors as in the second embodiment.

According to the fifth embodiment, the transistors 20, 20, 20-1, 20-2 for shorting are respectively arranged in one end portion of the plural memory strings 14-1 to 14-4 that lies on the sense amplifier 18 side, in the other end portion thereof that lies farthest apart from the sense amplifier 18 side and in the central portion of source line SL. Therefore, the follow-up operation for charge transfer in the second well region 13 with respect to source line SL can be further improved, and the speed of the read and the verify can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate of a first conductivity type;
a first well region of a second conductivity type arranged in the semiconductor substrate of the first conductivity type;
a second well region of the first conductivity type arranged in the first well region;
a memory string arranged in the second well region, the memory string including a plurality of memory cells and first and second select transistors;
a bit line connected to one end of the memory string;
a source line connected to the other end of the memory string; and
a first transistor arranged in the second well region, having first and second terminals and including a gate insulating film with first film thickness, the first terminal of the first transistor being connected to the source line and the second terminal thereof being connected to the second well region.

2. The device according to claim 1, wherein the first transistor is turned on at one of a data read time and erase time to short the source line to the second well region.

3. The device according to claim 2, further comprising a second transistor that applies an erase voltage to the second well region at the data erase time, the second transistor including a gate insulating film with second film thickness.

4. The device according to claim 3, wherein the first film thickness is smaller than the second film thickness.

5. The device according to claim 1, wherein the second well region comprises a plurality of memory strings and a plurality of first transistors, each of the first transistors has the first and second terminals, the first terminals of the first transistors are commonly connected to the source line via first contacts and the second terminals of the first transistors are commonly connected to a well interconnection that supplies a potential to the second well region via second contacts.

6. The device according to claim 5, further comprising a third transistor serially connected to the first transistor and including a gate insulating film with the first film thickness, the third transistor being formed in the second well region.

7. The device according to claim 6, wherein the third transistor is turned on together with the first transistor at one of a data read time and data erase time.

8. The device according to claim 1, further comprising a sense amplifier arranged in the semiconductor substrate and connected to one end of the bit line, the first transistor being connected to a source line of the memory string on the other end side of the bit line.

9. The device according to claim 8, wherein the second well region comprises a plurality of memory strings and a plurality of first transistors, each of the first transistors has first and second terminals, the first terminals of the first transistors are commonly connected to a first metal interconnection layer acting as the source line via first contacts and the second terminals of the first transistors are commonly connected to a second metal interconnection layer used as a well interconnection that supplies a potential to the second well region via second contacts.

10. The device according to claim 9, further comprising:
a third metal interconnection layer formed above the first metal interconnection layer;
a fourth metal interconnection layer formed above the second metal interconnection layer;
a plurality of third contacts that electrically connect the first metal interconnection layer to the third metal interconnection layer, the third contacts being arranged in a desired position between the first and third metal interconnection layers; and
a plurality of fourth contacts that electrically connect the second metal interconnection layer to the fourth metal interconnection layer, the fourth contacts being arranged in a desired position between the second and fourth metal interconnection layers.

11. A semiconductor memory device comprising:
a semiconductor substrate of a first conductivity type;
a first well region of a second conductivity type arranged in the substrate of the first conductivity type;
a second well region of the first conductivity type arranged in the first well region;
a plurality of memory strings arranged in the second well region, the plural memory strings being serially connected and each of the memory strings including a plurality of memory cells and first and second select transistors;
a bit line connected to one end of the memory string;
a source line connected to the other end of the memory string; and
first and second transistors serially connected between the plural memory strings and each including a gate insulating film with first film thickness, a connection node of the first and second transistors being connected to the second well region.

12. The device according to claim 11, wherein the first, second transistors are turned on at one of a data read time and erase time to short the source line to the second well region.

13. The device according to claim 12, further comprising a third transistor that applies an erase voltage to the second well region at the data erase time, the third transistor including a gate insulating film with second film thickness.

14. The device according to claim 13, wherein the first film thickness is smaller than the second film thickness.

15. The device according to claim 11, further comprising a fourth transistor having first and second terminals, the first terminal of the fourth transistor being connected to one end of the series-connected memory strings and the second terminal of the fourth transistor being connected to the second well region.

16. An erase method of a semiconductor memory device comprising:
applying a first voltage to a gate electrode of a first transistor connected between a source line connected to a memory string and a well region in which the memory string is formed to turn on the first transistor;
charging an interconnection connected to a sense amplifier to a second voltage that is lower than the first voltage; and
applying an erase voltage to the well region to charge a bit line and source line, the voltage of a gate electrode of the first transistor being set to a voltage that is higher than the erase voltage by the first voltage at this time.

17. The method according to claim 16, further comprising using a second transistor connected between the interconnection and the bit line, the second transistor being turned off when an erase voltage is applied to the well region.
